(19) United States
(12) Patent Application Publication
(10) Pub. No.: US 2013/0175577 A1
(43) Pub. Date: Jul. 11, 2013

(54) NFET Device with Tensile Stressed Channel Region and Methods of Forming Same

(71) Applicants: Chung Foong Tan, Dresden (DE); Maciej Wiatr, Dresden (DE); Stephan Kronholz, Dresden (DE)

(72) Inventors: Chung Foong Tan, Dresden (DE); Maciej Wiatr, Dresden (DE); Stephan Kronholz, Dresden (DE)

(73) Assignee: GLOBALFOUNDRIES INC., Grand Cayman (KY)

(21) Appl. No.: 13/346,299

(22) Filed: Jan. 9, 2012

(51) Int. Cl. H01L 27/092; H01L 29/78; H01L 21/28

(52) U.S. Cl. 257/190; 257/369; 438/585; 257/E27.062; 257/E29.255; 257/E21.19

(57) ABSTRACT

Disclosed herein is an NFET device with a tensile stressed channel region and various methods of making such an NFET device. In one example, the NFET transistor includes a semiconducting substrate, a first layer of semiconductor material positioned above the substrate, a second capping layer of semiconductor material positioned above the first layer of semiconductor material and a gate electrode structure positioned above the second capping layer of semiconductor material.

### BACKGROUND OF THE INVENTION

1. Field of the Invention

Generally, the present disclosure relates to the manufacturing of sophisticated semiconductor devices, and, more specifically, to an NFET device with a tensile stressed channel region and various methods of making such an NFET device.

2. Description of the Related Art

The fabrication of advanced integrated circuits, such as CPU's, storage devices, ASIC's (application specific integrated circuits) and the like, requires the formation of a large number of circuit elements in a given chip area according to a specified circuit layout, wherein field effect transistors (NFET and PFET transistors) represent one important type of circuit element used in manufacturing such integrated circuit devices. A field effect transistor, irrespective of whether an NFET transistor or a PFET transistor is considered, typically comprises doped source and drain regions that are formed in a semiconducting substrate that are separated by a channel region. A gate insulation layer is positioned above the channel region and a conductive gate electrode is positioned above the gate insulation layer. By applying an appropriate voltage to the gate electrode, the channel region becomes conductive and current is allowed to flow from the source region to the drain region.

Device designers are under constant pressure to increase the operating speed and electrical performance of transistors and integrated circuit products that employ such transistors. Given that the gate length (the distance between the source and drain regions) on modern transistor devices may be approximately 30-50 nm, and that further scaling is anticipated in the future, device designers have employed a variety of techniques in an effort to improve device performance, e.g., the use of high-k dielectrics, the use of metal gate electrode structures, the incorporation of work function metals in the gate electrode structure and the use of channel stress engineering techniques on transistors (create a tensile stress in the channel region for NFET transistors and create a compressive stress in the channel region for PFET transistors). Stress engineering techniques typically involve the formation of specifically made silicon nitride layers that are selectively formed above appropriate transistors, i.e., a layer of silicon nitride that is intended to impart a tensile stress in the channel region of an NFET transistor would only be formed above the NFET transistors. Such selective formation may be accomplished by masking the PFET transistors and then blanket depositing the layer of silicon nitride, or by initially blanket depositing the layer of silicon nitride across the entire substrate and then performing an etching process to selectively remove the silicon nitride from above the PFET transistors. Conversely, for PFET transistors, a layer of silicon nitride that is intended to impart a compressive stress in the channel region of a PFET transistor is formed above the PFET transistors. The techniques employed in forming such nitride layers with the desired tensile or compressive stress are well known to those skilled in the art. Other stress engineering techniques involve forming cavities in the substrate adjacent the gate electrode and thereafter forming a stressed semiconductor material, typically silicon germanium, in the cavities in an attempt to impart the desired stress to the channel region.

The present disclosure is directed to an NFET device with a tensile stressed channel region and various methods of making such an NFET device.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to an NFET device with a tensile stressed channel region and various methods of making such an NFET device. In one example, the NFET transistor includes a semiconducting substrate, a first layer of semiconductor material positioned above the substrate, a second capping layer of semiconductor material positioned above the first layer of semiconductor material and a gate electrode structure positioned above the second capping layer of semiconductor material.

In another illustrative example, a device disclosed herein includes a semiconducting substrate having an NFET region and a PFET region defined therein, a first layer of semiconductor material positioned above the substrate within both the NFET region and the PFET region and a second capping layer of semiconductor material positioned above the first layer of semiconductor material only within the NFET region. In this embodiment, the device also includes a gate electrode structure for the NFET transistor positioned above the NFET region and above the second capping layer of semiconductor material and a gate electrode structure for the PFET transistor positioned above the PFET region and above the first layer of semiconductor material.

One illustrative method disclosed herein includes forming a first layer of semiconductor material on an NFET region and on a PFET region of a semiconducting substrate, forming a second capping layer of semiconductor material above the first layer of semiconductor material only within the NFET region, forming a gate electrode structure for an NFET transistor above the NFET region and above the second capping layer of semiconductor material and forming a gate electrode structure for a PFET transistor above the PFET region and above the first layer of semiconductor material.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1D depict one illustrative process flow disclosed for forming an NFET device with a tensile stressed channel region.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

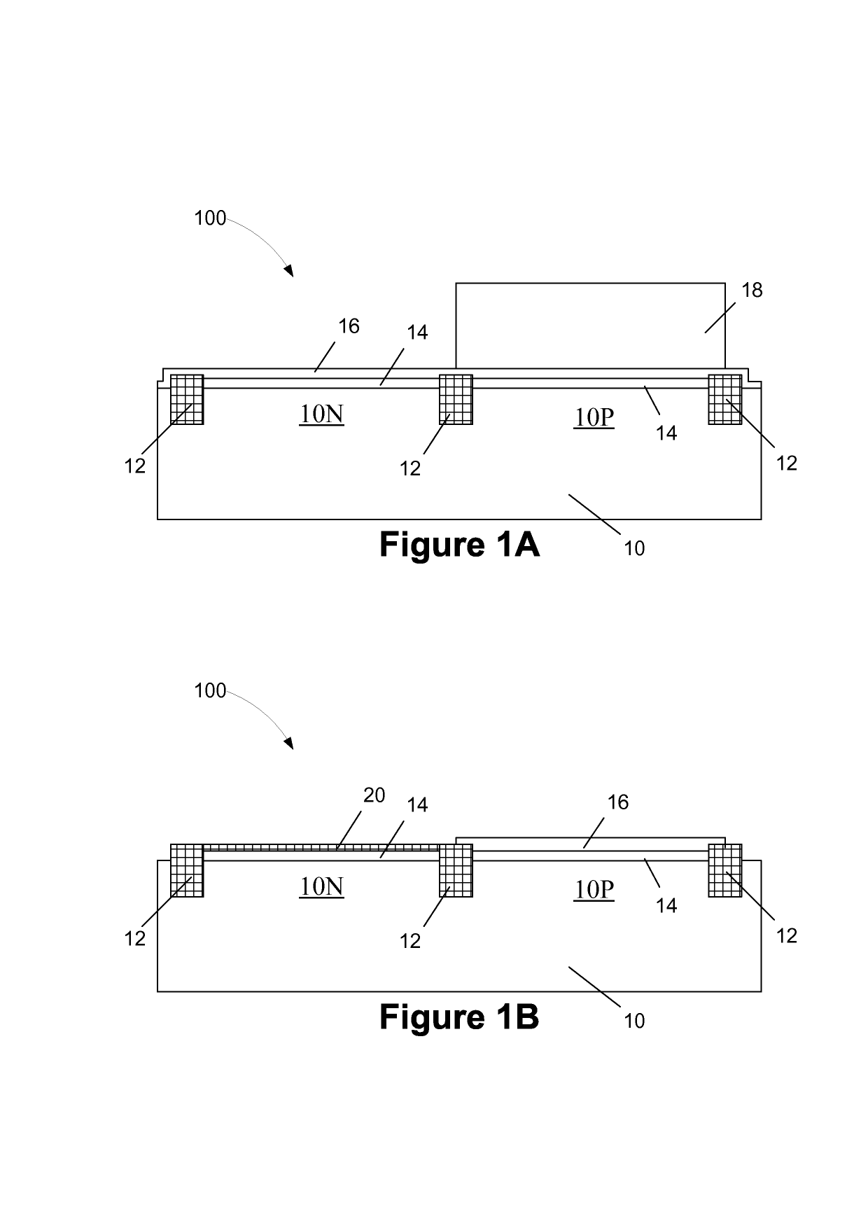

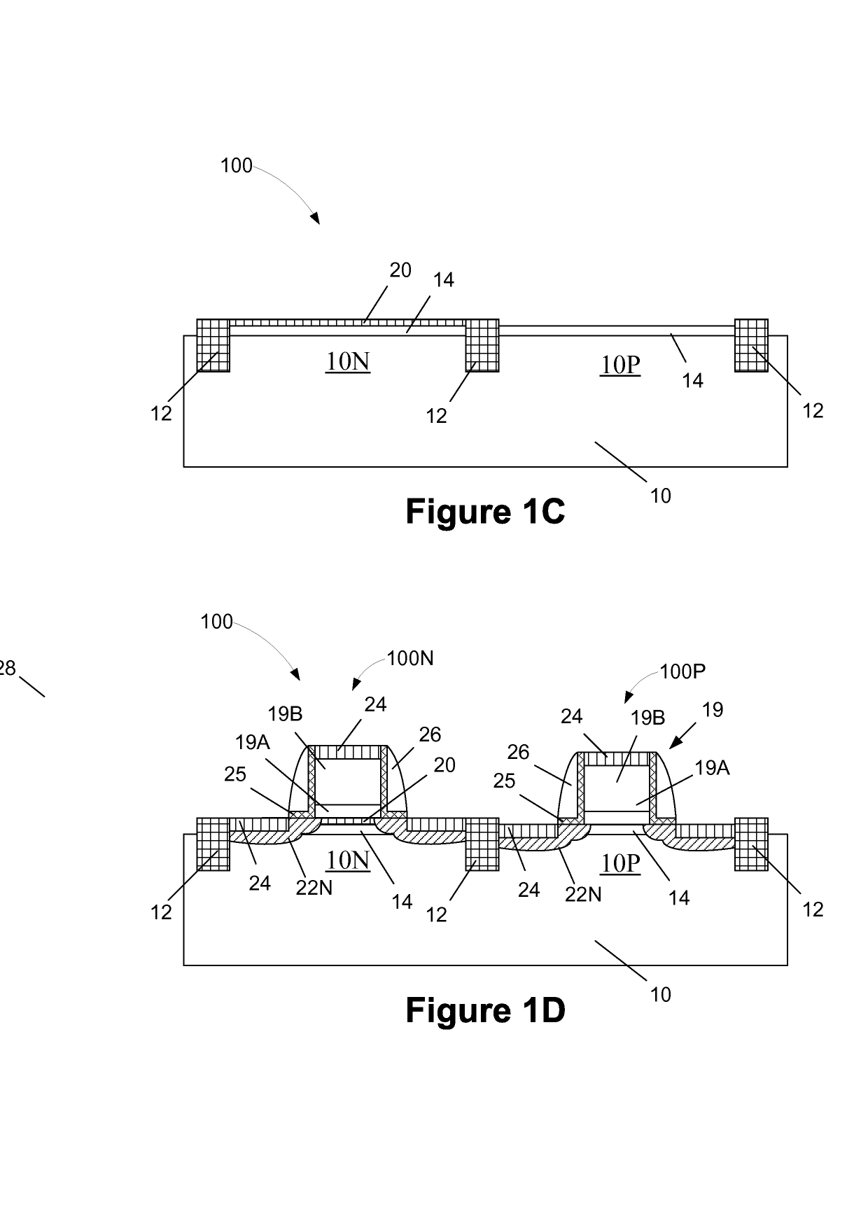

The present disclosure is directed to an NFET device with a tensile stressed channel region and various methods of making such an NFET device. In some cases, the methods and devices may include a high-k dielectric material (k value greater than 10) and a metal-containing electrode material. As will be readily apparent to those skilled in the art upon a complete reading of the present application, the present method is applicable to a variety of technologies, e.g., NFET, PFET, CMOS, etc., and is readily applicable to a variety of devices, including, but not limited to, logic devices, memory devices, resistors, conductive lines, etc. With reference to FIGS. 1A-1D, various illustrative embodiments of the methods and devices disclosed herein will now be described in more detail.

FIG. 1A is a simplified view of an illustrative semiconductor device 100 at an early stage of manufacturing. The semiconductor device 100 is formed above a semiconducting substrate 10 that is divided into an NFET region 10N and a PFET region 10P. The active regions 10N, 10P are defined by illustrative trench isolation structures 12 formed in the substrate 10. The substrate 10 may have a variety of configurations, such as the depicted bulk silicon configuration. The substrate 10 may also have a silicon-on-insulator (SOI) configuration that includes a bulk silicon layer, a buried insulation layer and an active layer, wherein semiconductor devices are formed in and above the active layer. Thus, the terms substrate or semiconductor substrate should be understood to cover all semiconductor structures. The substrate 10 may also be made of materials other than silicon. Although not depicted in FIG. 1A, an NFET transistor and a PFET transistor will be formed in and above the NFET region 10N and the PFET region 10P, respectively.

At the point of fabrication depicted in FIG. 1A, several process operations have been performed on the device 100. More specifically, a first layer of semiconductor material 14 has been formed on both the NFET region 10N and the PFET region 10P. In one illustrative embodiment, the first layer of semiconductor material 14 is a layer of silicon germanium that may be formed by performing an epitaxial deposition process. The thickness and germanium concentration of the illustrative first layer of silicon germanium may vary depending on the particular application. In one illustrative embodiment, the layer of silicon germanium may have a thickness within the range of 5-20 nm and a germanium concentration of 30-40%. With continuing reference to FIG. 1A, a hard mask layer 16 has been blanket deposited on the substrate 10. The hard mask layer 16 may be comprised of a variety of materials, e.g., silicon dioxide, silicon nitride, etc. In one illustrative embodiment, the hard mask layer 16 is a layer of silicon dioxide having a thickness of about 10-20 nm that is formed by a chemical vapor deposition (CVD) process. A patterned mask layer 18, e.g., a patterned photoresist mask, is then formed above the device 100 using known photolitho-graphic tools and techniques. The patterned mask layer 18 covers the PFET region 10P and exposes the NFET region 10N for further processing.

Next, as shown in FIG. 1B, an etching process has been performed through the patterned mask layer 18 to remove the exposed portions of the hard mask layer 16. The etching process may be either a wet or dry etching process. After the etching process is performed, the patterned mask layer 18 is removed using known techniques, e.g., ashing. Next, a second capping layer of semiconductor material 20 is selectively formed in only the NFET region 10N of the device 100. More precisely, the second capping layer of semiconductor material 20 is selectively formed on the first layer of semiconductor material 14 only in the NFET region 10N. In one illustrative embodiment, the second capping layer of semiconductor material 20 is a layer of pure silicon. In other applications, limited amounts of germanium, e.g., 1-7%, may be added to the second capping layer of semiconductor material 20. The second capping layer of semiconductor material 20 may have a thickness within the range of about 2-5 nm and if may be formed by performing an epitaxial deposition process. In some applications, the second capping layer of semiconductor material 20 may be a layer of silicon carbon, e.g., 1-2% carbon.

The second capping layer of semiconductor material 20 is formed so as to impart a desired tensile stress on the portions of the substrate 10 that will become the channel region for an NFET transistor to be formed in and above the NFET region 10N. The amount of stress in the second capping layer of semiconductor material 20 may be varied by varying the amount of germanium in the first layer of semiconductor material 14. In general, the greater the amount of germanium in the first semiconductor material layer 14 (when it is comprised of silicon germanium), the greater will be the tensile stress in the second capping layer of semiconducting material 20. Conversely, the lesser the amount of germanium in the first semiconductor material layer 14 (when it is comprised of silicon germanium), the lesser will be the tensile stress in the second capping layer of semiconducting material 20.

Next, as shown in FIG. 1C, an etching or cleaning process, wet or dry, is performed to remove the hard mask layer 16 from above the PFET region 10P. Thereafter, as shown in FIG. 1D, an illustrative NFET transistor 100N is formed in and above the NFET region 10N and an illustrative PFET transistor 100P is formed in and above the PFET region 10P. The particular materials of construction and techniques employed in forming the illustrative transistors 100N, 100P should not be considered to be a limitation of the present inventions. In the illustrative examples depicted herein, each of the NFET transistor 100N and the PFET transistor 100P includes a schematically depicted gate electrode structure 19 that typically includes an illustrative gate insulation layer 19A and an illustrative gate electrode 19B. The gate insulation layer 19A may be comprised of a variety of different materials, such as, for example, silicon dioxide, a so-called high-k (k greater than 10) insulation material, etc. Similarly, the gate electrode 19B may also be of a material such as polysilicon or amorphous silicon, or it may be comprised of one or more metal layers that act as the gate electrode 19B. As will be recognized by those skilled in the art after a complete reading of the present application, the gate electrode structures 19 of the device 100 depicted in the drawings, i.e., the gate insulation layer 19A and the gate electrode 19B, is intended to be representative in nature. That is, the gate electrode structures 19 may be comprised of a variety of different materials and they may have a variety of configurations, and the gate electrode structures 19 may be made using either so-called “gate-first” or “gate-last” techniques. The gate electrode structure 19 for the NFET transistor 100N may contain different materials than the gate electrode structure 19 of the PFET transistor 100P. For ease of explanation, the illustrative transistors 100N, 100P will be depicted as having polysilicon gate electrodes 19B, however, the present invention should not be considered as limited to such an illustrative embodiment.

Also as depicted in FIG. 1D, each of the transistors 100N, 100P also includes a plurality of source/drain regions 22N, 22P, respectively, a liner layer 25, a sidewall spacer 26, and metal silicide regions 24 formed in the source/drain regions 22N, 22P and on the gate electrodes 19B. The various structures and regions of the transistors 100N, 100P depicted in FIG. 1D may be formed by performing well-known processes. For example, the gate structures 19 may be formed by depositing various layers of material and thereafter performing one or more etching processes to define the basic layer stack of the gate electrode structures 19. The liner layer 25 may be comprised of a relatively thin, e.g., 2-3 nm, layer of, for example, silicon dioxide, that is formed by performing a conformal chemical vapor deposition (CVD) process. The spacer 26 may be formed by depositing a layer of spacer material, such as silicon nitride, and thereafter performing an anisotropic etching process on the layer of spacer material. The source/drain regions 22N, 22P may be formed using known ion implantation techniques using the appropriate dopant materials, i.e., N-type dopants and P-type dopants, respectively. The metal silicide regions 24 may be formed by performing traditional silicidation processes, i.e., depositing a layer of refractory metal, performing a heating process causing the refractory metal to react with underlying silicon-containing material, removing unreacted portions of the layer of refractory metal (e.g., nickel, platinum, or combinations thereof), followed perhaps by performing an additional heating process. Thereafter, conductive contacts (not shown) are formed on the device 100 using traditional materials and techniques, and various metallization structures, e.g., conductive lines and vias (not shown), are formed above the device 100.

As can be seen in FIG. 1D, the gate insulation layer 19A of the NFET transistor 100N is formed above both the first and second layers of semiconductor material 14, 20, respectively. In contrast, only the first layer of semiconductor material 14 is present in the PFET region 10P. Due to the presence of the second layer of semiconductor material 20 in the NFET region 10N, and the tensile stress it induces in the channel region of the NFET transistor 100N, the electrical performance characteristics of the NFET transistor 100N may be improved relative to prior art NFET transistors without such a configuration.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. An NFET transistor, comprising:
a semiconducting substrate;
a first layer of semiconductor material positioned above said substrate;
a second capping layer of semiconductor material positioned above said first layer of semiconductor material; and
a gate electrode structure positioned above said second capping layer of semiconductor material.

2. The device of claim 1, wherein said first layer of semiconductor material is comprised of silicon germanium or silicon carbon.

3. The device of claim 2, wherein said second capping layer of semiconductor material is comprised of pure silicon, silicon germanium or silicon carbon.

4. The device of claim 1, wherein said first layer of semiconductor material is comprised of silicon germanium having a germanium concentration of 30-40% and wherein said second capping layer of semiconductor material is comprised of pure silicon, silicon germanium having a germanium concentration of 1-7% or silicon carbon.

5. The device of claim 1, further comprising a plurality of N-doped source/drain regions formed at least partially in said substrate proximate said gate electrode structure.

6. The device of claim 1, wherein said gate electrode structure comprises a gate insulation layer positioned on said second capping layer of semiconductor material.

7. The device of claim 1, wherein said first layer of semiconductor material is formed on said substrate, said second capping layer of semiconductor material is formed on said first layer of semiconductor material, and wherein said gate electrode structure comprises a gate insulation layer positioned on said second capping layer of semiconductor material.

8. The device of claim 1, wherein said second capping layer of semiconductor material is adapted to induce a tensile stress in a channel region of said NFET transistor.

9. An NFET transistor, comprising:
a semiconducting substrate;
a first layer of semiconductor material positioned on said substrate, wherein said first layer of semiconductor material is comprised of silicon germanium or silicon carbon;
a second capping layer of semiconductor material positioned on said first layer of semiconductor material, wherein said second capping layer of semiconductor material is adapted to induce a tensile stress in a channel region of said NFET transistor; and
a gate electrode structure positioned on said second capping layer of semiconductor material.

10. The device of claim 9, wherein said second capping layer of semiconductor material is comprised of pure silicon, silicon germanium or silicon carbon.

11. The device of claim 9, further comprising a plurality of N-doped source/drain regions formed at least partially in said substrate proximate said gate electrode structure.

12. A device comprising an NFET transistor and a PFET transistor, comprising:
a semiconducting substrate having an NFET region and a PFET region defined therein;
a first layer of semiconductor material positioned above said substrate within both said NFET region and said PFET region;
a second capping layer of semiconductor material positioned above said first layer of semiconductor material only within said NFET region;
a gate electrode structure for said NFET transistor positioned above said NFET region and above said second capping layer of semiconductor material; and
a gate electrode structure for said PFET transistor positioned above said PFET region and above said first layer of semiconductor material.

13. The device of claim 12, wherein said gate electrode structure for said NFET transistor comprises a gate insulation layer that is positioned on said second capping layer of semiconductor material within said NFET region and wherein said gate electrode structure for said PFET transistor comprises a gate insulation layer that is positioned on said first semiconductor material layer within said PFET region.

14. The device of claim 12, wherein said first layer of semiconductor material is comprised of silicon germanium or silicon carbon.

15. The device of claim 14, wherein said second capping layer of semiconductor material is comprised of pure silicon, silicon germanium or silicon carbon.

16. The device of claim 12, wherein said first layer of semiconductor material is comprised of silicon germanium having a germanium concentration of 30-40% and wherein said second capping layer of semiconductor material is comprised of pure silicon, silicon germanium having a germanium concentration of 1-7% or silicon carbon.

17. The device of claim 12, further comprising:
a plurality of N-doped source/drain regions formed at least partially in said substrate proximate said gate electrode structure for said NFET transistor; and
a plurality of N-doped source/drain regions formed at least partially in said substrate proximate said gate electrode structure for said PFET transistor.

18. The device of claim 12, wherein said first layer of semiconductor material is formed on said substrate, said second capping layer of semiconductor material is formed on said first layer of semiconductor material in said NFET region, said gate electrode structure for said NFET transistor comprises a gate insulation layer positioned on said second capping layer of semiconductor material and said gate electrode structure for said PFET transistor comprises a gate insulation layer positioned on said first semiconductor material layer.

19. The device of claim 12, wherein said second capping layer of semiconductor material is adapted to induce a tensile stress in a channel region of said NFET transistor.

20. A device comprising an NFET transistor and a PFET transistor, comprising:
a semiconducting substrate having an NFET region and a PFET region defined therein;
a first layer of semiconductor material positioned on said substrate within both said NFET region and said PFET region;
a second capping layer of semiconductor material positioned on said first layer of semiconductor material only within said NFET region, wherein said second capping layer of semiconductor material is adapted to induce a tensile stress in a channel region of said NFET transistor;
a gate electrode structure for said NFET transistor positioned above said NFET region and above said second capping layer of semiconductor material; and
a gate electrode structure for said PFET transistor positioned above said PFET region and above said first layer of semiconductor material.

21. The device of claim 20, wherein said gate electrode structure for said NFET transistor comprises a gate insulation layer that is positioned on said second capping semiconductor material layer within said NFET region and wherein said gate electrode structure for said PFET transistor comprises a gate insulation layer that is positioned on said first semiconductor material layer within said PFET region.

22. The device of claim 20, wherein said second capping layer of semiconductor material is comprised of pure silicon, silicon germanium or silicon carbon.

23. The device of claim 20, wherein said first layer of semiconductor material is comprised of silicon germanium having a germanium concentration of 30-40% and wherein said second capping layer of semiconductor material is comprised of pure silicon, silicon germanium having a germanium concentration of 1-7% or silicon carbon.

24. A method, comprising:
forming a first layer of semiconductor material on an NFET region and on a PFET region of a semiconducting substrate;
forming a second capping layer of semiconductor material above said first layer of semiconductor material only within said NFET region;
forming a gate electrode structure for an NFET transistor above said NFET region and above said second capping layer of semiconductor material; and
forming a gate electrode structure for a PFET transistor above said PFET region and above said first layer of semiconductor material.

25. The method of claim 24, wherein forming said second capping layer of semiconductor material comprises forming said second capping layer of semiconductor material so as to induce a tensile stress in said NFET region.
